(19) United States
(12) Patent Application Publication
(10) Pub. No.: US 2026/0066894 A1
(43) Pub. Date: Mar. 5, 2026

(54) GATE DRIVING DEVICE

(71) Applicant: Mitsubishi Electric Corporation, Tokyo (JP)

(72) Inventors: Hajime TOYODA, Tokyo (JP); Kohei ONDA, Tokyo (JP)

(73) Assignee: Mitsubishi Electric Corporation, Tokyo (JP)

(21) Appl. No.: 19/104,778

(22) PCT Filed: Sep. 2, 2022
(86) PCT No.: PCT/JP2022/033129

§ 371 Date: Feb. 19, 2025

(51) Int. Cl. H03K 17/16; H02M 1/088

(52) U.S. Cl. CPC H03K 17/162; H02M 1/088

(57) ABSTRACT

An object is to obtain a gate driving device capable of further reducing noise than conventional ones. A gate driving device includes a command generation circuit which generates and outputs a gate drive command on the basis of an input signal, a constant output circuit which is connected in parallel to the command generation circuit and outputs a constant voltage signal on the basis of the input signal, a complementary emitter follower circuit which amplifies the gate drive command, and a current limitation element which is provided on the input side or the output side of the complementary emitter follower circuit and which suppresses the backflow of current. The gate driving device applies a gate drive voltage obtained by combining the gate drive command and the constant voltage signal to the gate terminal of a semiconductor switching element.

### TECHNICAL FIELD

The present disclosure relates to a gate driving device.

### BACKGROUND ART

Some voltage-driven elements included in a semiconductor power conversion device are controlled to be turned on or off by a gate driving device. In some conventional gate driving devices, a waveform shaping circuit which shapes an input voltage signal changing stepwise to generate a voltage waveform having a predetermined rate of voltage change, and a complementary emitter follower circuit or a complementary source follower circuit with the input side connected to the output of the waveform shaping circuit and the output side connected to the gate terminal of the voltage-driven element, are provided, and the emitter terminal or the source terminal of the voltage-driven element is connected to an intermediate connection point between a forward bias power supply for supplying a forward bias voltage and a reverse bias power supply for supplying a reverse bias voltage (e.g., see Patent Document 1). A waveform shaping circuit of a gate driving device disclosed in Patent Document 1 is so configured that a resistor and a capacitor are connected in an inverted-L shape, and outputs a first-order lag waveform based on a time constant for the resistor and the capacitor.

### CITATION LIST

### Patent Document

Patent Document 1: Japanese Laid-Open Patent Publication No. 2004-48959

### SUMMARY OF THE INVENTION

### Problem to be Solved by the Invention

In the gate driving device disclosed in Patent Document 1, noise (switching noise) caused by change of current with respect to time (dI/dt) in current rise before the Miller period can be suppressed by appropriately setting the time constant for the waveform shaping circuit. Meanwhile, since only one time constant may be set for the waveform shaping circuit, a gate drive current is increased in the Miller period when a voltage drop occurs, and change of voltage with respect to time (dV/dt) in a voltage fall steepens, so that noise caused by change of voltage with respect to time may be increased.

The present disclosure has been made to solve the problems as described above. An object of the present disclosure is to obtain a gate driving device capable of further reducing noise than conventional ones.

### Means to Solve the Problem

A gate driving device according to the present disclosure includes: a command generation circuit which generates and outputs a gate drive command on the basis of an input signal; a constant output circuit which is connected in parallel to the command generation circuit and outputs a constant voltage signal or a constant current signal on the basis of the input signal; an amplification circuit which amplifies the gate drive command; and a current limitation element which is provided on an input side or an output side of the amplification circuit and which suppresses a backflow of current, wherein the gate driving device applies a gate drive voltage obtained by combining the gate drive command and the constant voltage signal or the constant current signal, to a gate terminal of a semiconductor switching element.

### Effect of the Invention

The gate driving device according to the present disclosure can further reduce noise than conventional ones.

### BRIEF DESCRIPTION OF THE DRAWINGS

FIG. 1 is a circuit diagram showing a gate driving device according to embodiment 1.

FIG. 2A is a configuration diagram showing an example in which the gate driving device in embodiment 1 is applied.

FIG. 2B is a configuration diagram showing an example in which the gate driving device in embodiment 1 is applied and MOSFETs are used as semiconductor switching elements.

FIG. 3 schematically shows operation waveforms in the gate driving device in embodiment 1.

FIG. 4A schematically shows operation waveforms when a main circuit carries rated current.

FIG. 4B schematically shows operation waveforms when the main circuit carries small current.

FIG. 5A schematically shows operation waveforms according to a comparative example when a main circuit carries large current.

FIG. 5B shows operation waveforms according to embodiment 1 when the main circuit carries large current.

FIG. 5C shows operation waveforms according to the comparative example when the main circuit carries small current.

FIG. 5D shows operation waveforms according to embodiment 1 when the main circuit carries small current.

FIG. 6 is a circuit diagram showing a gate driving device in embodiment 2.

FIG. 7A shows operation waveforms according to embodiment 2 when a main circuit carries large current.

FIG. 7B shows operation waveforms according to embodiment 2 when the main circuit carries small current.

FIG. 8 is a circuit diagram showing a gate driving device in embodiment 3.

FIG. 9 is a circuit diagram showing a modification of the gate driving device in embodiment 3.

FIG. 10 is a circuit diagram showing a gate driving device in embodiment 4.

FIG. 11 shows operation waveforms according to embodiment 4 when a main circuit carries large current.

### DESCRIPTION OF EMBODIMENTS

### Embodiment 1

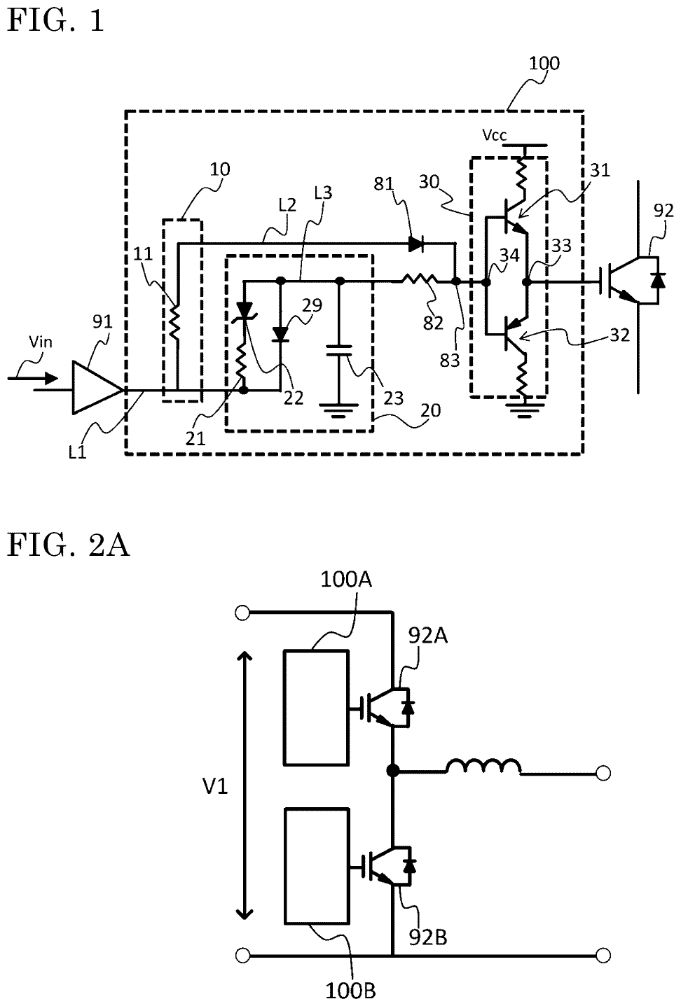

Embodiment 1 will be described with reference to FIG. 1 to FIG. 5D. FIG. 1 is a circuit diagram showing a gate driving device in embodiment 1. A gate driving device 100 has an input side connected to an interface circuit 91 and an output side connected to a semiconductor switching element 92. On the basis on an input signal Vin inputted via the interface circuit 91, the gate driving device 100 generates a gate drive signal, that is, a gate drive voltage, and outputs the gate drive signal to the gate terminal of the semiconductor switching element 92. The gate driving device 100 includes a constant output circuit 10, a command generation circuit 20, a current limitation element 82, and a complementary emitter follower circuit 30, that is, an amplification circuit, and the constant output circuit 10 and the command generation circuit 20 are connected in parallel to each other. The constant output circuit 10 is connected to the input side of the complementary emitter follower circuit 30 via a diode 81 and a connection point 83. The connection point 83 is provided between the current limitation element 82 and the complementary emitter follower circuit 30. The command generation circuit 20 is connected to the input side of the complementary emitter follower circuit 30 via the current limitation element 82 and the connection point 83.

The constant output circuit 10 includes a resistor 11 provided between an electric path L1 on the ground side and an electric path L2 on the high-potential side, and is a constant voltage output circuit which outputs a constant voltage signal, and the output terminal of the constant output circuit 10 is connected to the anode of the diode 81. The cathode of the diode 81 is connected to the connection point 83.

The command generation circuit 20 includes an RC resonance circuit composed of a resistor 21 and a capacitor 23. The command generation circuit 20 shapes the input signal Vin, which is a step-shaped voltage signal, into a command waveform having a predetermined rate of voltage change, and outputs the shaped signal as a gate drive command. The command generation circuit 20 is composed of a series-connected assembly of the resistor 21 and a zener diode 22, a diode 29, and the capacitor 23 connected in parallel to each other. The resistor 21 is provided between the electric path L1 on the ground side and an electric path L3 on the high-potential side, and is connected to the cathode of the zener diode 22 on the high-potential side. The zener diode 22 and the diode 29 are provided such that a direction from the electric path L3 on the high-potential side to the electric path L1 on the ground side is a forward direction. One end of the capacitor 23 is grounded and the other end thereof is connected to the electric path L3 on the high-potential side. The output of the command generation circuit 20 is inputted to the complementary emitter follower circuit 30 via the current limitation element 82 and the connection point 83.

The zener diode 22 is one example of a constant voltage element, and clamps the voltage at predetermined breakdown voltage so as to keep the gate drive command at the breakdown voltage as described below. In addition, in embodiment 1, the breakdown voltage of the zener diode 22 and a Miller voltage of the semiconductor switching element 92 are set to be equal to each other.

The complementary emitter follower circuit 30 is a circuit composed of an npn transistor 31, a pnp transistor, and 32 connected in series, and a connection point 33 between the emitter of the npn transistor 31 and the emitter of the pnp transistor, as an output end of the complementary emitter follower circuit 30, is connected to the gate terminal of the semiconductor switching element 92. In addition, a connection point 34 between the base of the npn transistor 31 and the base of the pnp transistor is an input end of the complementary emitter follower circuit 30. The collector of the npn transistor 31 is connected to an external power supply with the power supply voltage of Vcc via a resistor. The collector of the pnp transistor 32 is grounded via a resistor. In embodiment 1, the output of the complementary emitter follower circuit 30 is the output of the gate driving device 100.

The complementary emitter follower circuit 30 functions as an amplification circuit, and at least amplifies the gate drive command which is the output of the command generation circuit 20. The complementary emitter follower circuit 30 as described above is used in embodiment 1, but a complementary source follower circuit composed of an N-channel metal oxide semiconductor field effect transistor (MOSFET) and a P-channel. MOSFET may be used, instead of the complementary emitter follower circuit 30.

The current limitation element 82 is provided between the command generation circuit 20 and the connection point 83 on the electric path L3, and by the electromotive voltage, suppresses current from the output side from flowing reversely and entering the command generation circuit 20. In embodiment 1, a resistor is used as the current limitation element 82, but a reactor may be used instead of the resistor.

The semiconductor switching element 92 is an insulated gate bipolar transistor (IGBT) to which a diode is connected in anti-parallel in embodiment 1, but may be a MOSFET in which a diode is connected between the source and the drain, or a cascode-type gallium nitride-high mobility transistor (GaN-HEMT). The semiconductor switching element 92 is not particularly limited.

A constant voltage signal which is the output of the constant output circuit 10 and the gate drive command which is the output of the command generation circuit 20 are combined at the connection point 83, and the combined signal is amplified through the complementary emitter follower circuit 30, and then is outputted as a gate drive voltage which is the output of the gate driving device 100. The gate drive voltage is applied to the gate terminal of the semiconductor switching element 92.

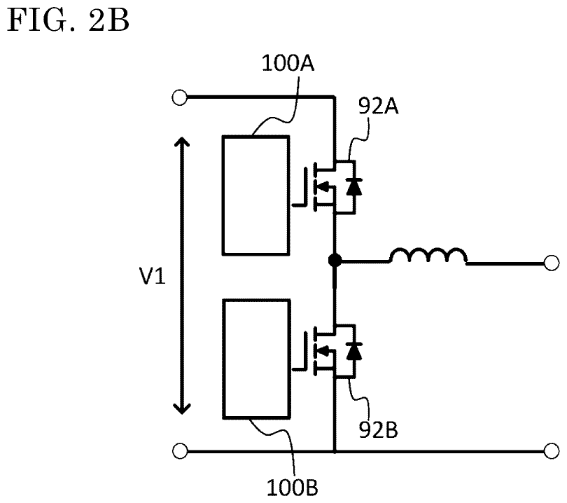

FIG. 2A is a configuration diagram showing an example in which the gate driving device in embodiment 1 is applied to, for example, a chopper circuit of a power converter. In FIG. 2A, the semiconductor switching elements 92 and gate driving devices 100 are represented as an upper-side semiconductor switching element 92A and a gate driving device 100A on the positive side (high side), and a lower-side semiconductor switching element 92B and a gate driving device 100B on the negative side (low side), respectively. In FIG. 2A, V1 represents the potential difference between the ground side and the high-potential side of the chopper circuit. FIG. 2B is a diagram in which the upper-side semiconductor switching element 92A and the lower-side semiconductor switching element 92B in FIG. 2A are respectively replaced with MOSFETs. The circuit configurations in FIG. 2A and FIG. 2B are for a chopper circuit. However, embodiment 1 can be applied to a circuit in which two semiconductor switching elements are connected in series and compose a leg as in FIG. 2A and FIG. 2B. For example, embodiment 1 may be applied to an inverter circuit composed of six elements or may be applied to a full-bridge circuit composed of four elements. In addition, both the elements connected in series need not be semiconductor switching elements, and one thereof may be a diode element.

Next, turn-on operation of the semiconductor switching element 92 by gate driving of the gate driving device 100 will be described. The input signal Vin as a gate signal is inputted to the gate driving device 100 via the interface circuit 91. The input signal Vin is a voltage signal which changes stepwise. The constant output circuit 10 and the command generation circuit 20 are connected in parallel to each other, and thus the input signal Vin is inputted to the respective circuits, the outputs of which are combined at the connection point 83.

The constant voltage signal which is the output of the constant output circuit 10 is determined by the input signal Vin and a resistance value of the resistor 11. The command generation circuit 20 functions as a low-impedance voltage supply having a combination of the zener diode 22 and the RC resonance circuit composed of the resistor 21 and the capacitor 23, and a waveform of the gate drive command which is the output of the command generation circuit 20 becomes a voltage waveform with first-order lag function characteristics. The specific waveform is determined by the input signal Vin and circuit constants for the resistor 21 and the capacitor 23.

As described above, the output of the constant output circuit 10 and the output of the command generation circuit 20 are combined at the connection point 83, and are inputted to the complementary emitter follower circuit 30, and thus the signal inputted to the complementary emitter follower circuit 30 and a signal transmitted from the complementary emitter follower circuit 30 to the semiconductor switching element 92 usually have the waveform of signal with greater output. In embodiment 1, a circuit constant is set such that the output of the command generation circuit 20 is greater. Thus, the waveform of a signal inputted to the complementary emitter follower circuit 30 and the waveform of the drive signal transmitted to the semiconductor switching element 92 are approximately the same as the waveform of the gate drive command which is the output of the command generation circuit 20.

In addition, as described above, the zener diode 22 provided in the command generation circuit 20 clamps the voltage at the predetermined breakdown voltage, and thus the output current of the constant output circuit 10 and the output current of the command generation circuit 20 satisfy the relationship represented by the following inequality (1).

$$[ Math . 1 ]$$

$$\{ \begin{matrix}{I}_{act} > {I}_{const} ( {V}_{z} \geq {V}_{gate} ) \\ {I}_{const} \geq {I}_{act} ( {V}_{gate} > {V}_{z} )\end{matrix} \qquad ( 1 )$$

In inequality (1), Iconst represents the output current of the constant output circuit 10, and Iact represents the output current of the command generation circuit 20. Vgate represents a output voltage of the gate driving device 100, and is a gate drive voltage. Vz represents the breakdown voltage of the zener diode 22. In addition, as described above, the breakdown voltage of the zener diode 22 and the Miller voltage of the semiconductor switching element 92 are set to be equal to each other in embodiment 1. Thus, in the case where Vmiller represents the Miller voltage of the semiconductor switching element 92, the following equation (2) is also satisfied in embodiment 1.

$$Vz = Vmiller \qquad ( 2 )$$

According to inequality (1) and equation (2), when the gate drive voltage Vgate is greater than the Miller voltage Vmiller of the semiconductor switching element 92, the output current Iconst of the constant output circuit 10 becomes equal to or greater than the output current Iact of the command generation circuit 20. Even in such a case, the backflow of current is suppressed by the effect of the electromotive voltage of the current limitation element 82, so that the output current Iconst of the constant output circuit 10 is suppressed from entering the command generation circuit 20. This means that all the output current Iconst of the constant output circuit 10 is inputted to the complementary emitter follower circuit 30, so that a gate current flows to the semiconductor switching element 92, and a gate drive by the constant output circuit 10 is not hindered.

Although the breakdown voltage of the zener diode 22 and the Miller voltage Vmiller are equal to each other in embodiment 1, the breakdown voltage of the zener diode 22 may be different from the power supply voltage Vcc of the external power supply for the complementary emitter follower circuit 30, more specifically, certain voltage lower than the power supply voltage Vcc, and need not be equal to the Miller voltage Vmiller.

In turn-on operation by the gate driving device 100, the output of the command generation circuit 20 causes great change of current with respect to time (dI/dt) at the start of the turn-on operation, and the di/dt gradually decreases. Thus, a current rise is fast, and increase in switching loss at the start of the turn-on operation is suppressed. After the Miller period is reached, the voltage drop is inhibited by the output of the constant output circuit 10, so that change of voltage with respect time (dV/dt) in the voltage fall is prevented from steepening. Accordingly, noise (noise caused by change of recovery voltage with respect to time) can be suppressed from being generated in a pair of semiconductor switching elements in the chopper circuit or the like. As described above, the gate drive is performed using a signal having a combination of the gate drive command and the constant voltage signal, whereby increase in switching loss in the turn-on operation and generation of noise can be suppressed.

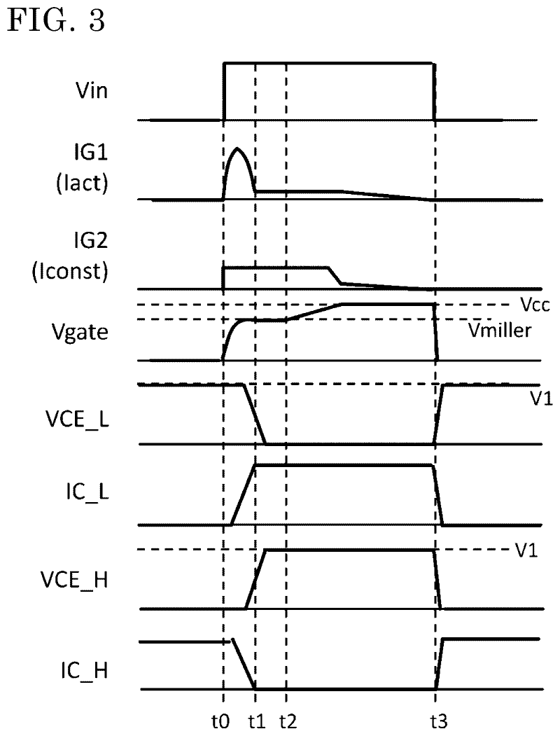

Next, operation waveforms in the gate driving device of embodiment 1 will be described. FIG. 3 schematically shows the respective operation waveforms in the gate driving device in embodiment 1, and the operation waveforms indicate a behavior in a case where the lower-side semiconductor switching element 92B of the chopper circuit as in FIG. 2A is turned on. In FIG. 3, the horizontal axis indicates time, and schematic waveforms of the input signal Vin, an output current IG1 (equal to Iact in inequality (1)) of the command generation circuit 20, an output current IG2 (equal to Iconst in inequality (1)) of the constant output circuit 10, a gate drive voltage Vgate, a voltage (voltage between the collector and the emitter) VCE_L of the lower-side semiconductor switching element 92B, a current (collector current) IC_L of the lower-side semiconductor switching element 92B, a voltage (voltage between the collector and the emitter) VCE_H of the upper-side semiconductor switching element 92A, and a current (collector current) IC_H of the upper-side semiconductor switching element 92A, are shown.

In FIG. 3, the time when the input signal Vin rises is denoted by time to. That is, before time to, the input signal Vin indicates zero or is in a negative bias state. At this time, the lower-side semiconductor switching element 92B is in an OFF state, and the upper-side semiconductor switching element 92A is in an ON state. In addition, the constant output circuit 10, the command generation circuit 20, and the gate driving device 100 output nothing.

The input signal Vin turns to positive at time to, and thus the output current IG1 of the command generation circuit 20, the output current IG2 of the constant output circuit 10, and the gate drive voltage Vgate rise. Accordingly, the lower-side semiconductor switching element 92B starts turn-on operation. Simultaneously, the upper-side semiconductor switching element 92A starts turn-off operation.

The period from time t0 to time t1 is before the Miller period. In this period, the output of the command generation circuit 20 is great, and the gate drive voltage Vgate becomes a voltage waveform having first-order lag function characteristics as in the output of the command generation circuit 20. In addition, during the period from time t0 to time t1, large gate current flows in the lower-side semiconductor switching element 92B and the gate drive voltage Vgate exceeds a gate threshold voltage (not shown), and thus the current IC_L of the lower-side semiconductor switching element 92B starts sharply rising. At the timing when the gate drive voltage Vgate reaches the Miller voltage Vmiller, the zener diode 22 clamps the voltage, so that the gate drive voltage Vgate is not increased beyond the Miller voltage. In addition, the output current IG1 of the command generation circuit 20 is also inhibited, and the gate current for the lower-side semiconductor switching element 92B is also inhibited.

The period from time t1 to time t2 is the Miller period. Here, the output of the command generation circuit 20 is limited through the zener diode 22. In this period, the output current IG2 of the constant output circuit 10 is greater than the output current IG1 of the command generation circuit 20, and the gate drive is achieved mainly using the output of the constant output circuit 10. Here, the output of the constant output circuit 10 is low, and thus a gradual gate drive is performed and the voltage VCE_L falls so as to slope gently.

The period from time t2 to time t3 is after the Miller period. Here, the gate drive voltage Vgate rises to Vcc (the power supply voltage of the external power supply) solely by the output of the constant output circuit 10, and the turn-on operation of the lower-side semiconductor switching element 92B is completed.

When time t3 is reached, the lower-side semiconductor switching element 92B starts turn-off operation. The turn-off operation in embodiment 1 is the same as that in normal constant voltage drive.

As described above, in embodiment 1, in an initial period of turn-on start, the gate drive is performed using the great output of the command generation circuit 20 to suppress occurrence of switching loss, and in and after the Miller period, the gate drive is performed by the gradual output of the constant output circuit 10, to prevent change of voltage with respect to time in voltage fall from steepening and also to prevent generation of noise. In other words, in embodiment 1, the generation of noise caused by change of voltage with respect to time in voltage fall is prevented, whereby noise can be further suppressed than in the conventional configuration and, further, occurrence of switching loss can also be suppressed.

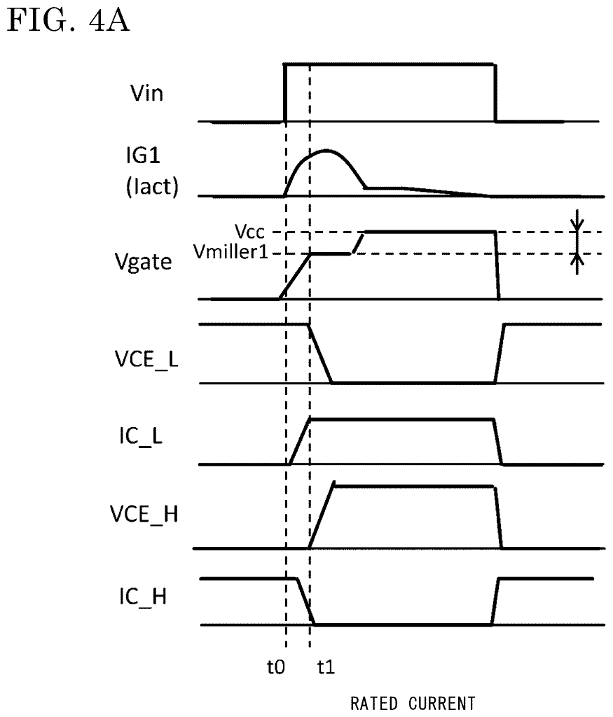

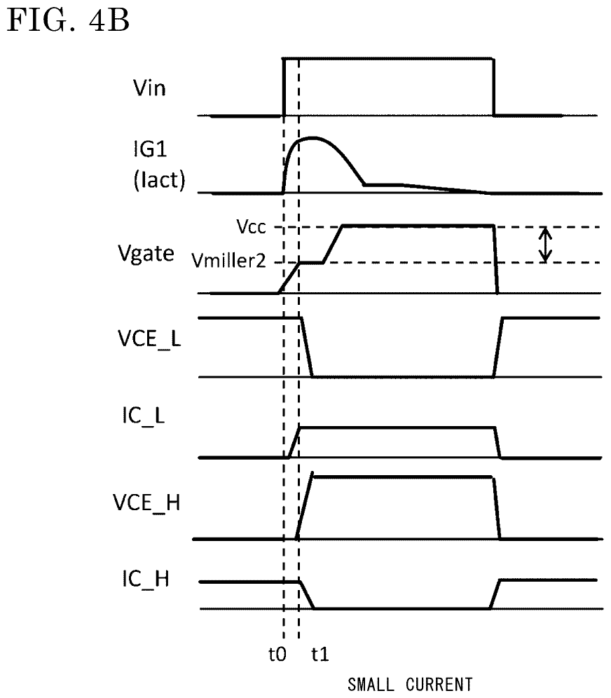

In embodiment 1, robustness with respect to change in current in a main circuit is also improved. Hereinafter, the description will be made. FIG. 4A schematically shows operation waveforms when the main circuit carries a rated current, and FIG. 4B schematically shows operation waveforms when the main circuit carries a small current. Here, “small current” refers to current smaller than the rated current and, for example, may be 10 A. When the main circuit carries the small current, there is a characteristic that a gate electric charge is small and the Miller voltage is low. That is, a Miller voltage Vmiller2 when the small current is carried is lower than a Miller voltage Vmiller1 when the rated current is carried.

Under a condition having such characteristics, in a gate drive using a first-order lag drive command based on an RC resonance circuit in a conventional configuration or a constant voltage drive, if a circuit constant is set so as to correspond to the case where the main circuit carries the rated current, a gate drive capability is excessively increased when the small current is carried, so that the gate drive voltage Vgate may be increased to Vcc before the Miller period is reached. In addition, if the gate drive voltage Vgate is increased to Vcc before the Miller period is reached, the gate current is excessively increased in the Miller period, whereby change of the voltage VCE_L with respect to time (dV/dt) in voltage fall, and change of the voltage VCE_H with respect to time (dV/dt) in voltage rise for the paired semiconductor switching element is increased. The increase in the change of voltage with respect to time leads to generation of noise. If the circuit constant is set so as to correspond to small current, generation of noise is suppressed, but when the rated current is carried and when a large current is carried, the gate drive capability decreases, and the current rise is delayed, so that switching loss may be increased. As described above, in the conventional configuration, change in current in the main circuit greatly changes the gate drive capability, and it is difficult to suppress both switching loss when rated current is carried and when the large current is carried and generation of noise when the small current is carried. Here, “large current” refers to current larger than the rated current and, for example, may be 50 A.

In the gate driving device 100 in embodiment 1, the voltage of the RC resonance circuit of the command generation circuit 20 is clamped at the Miller voltage Vmiller using the zener diode 22. Accordingly, the output current IG1 of the command generation circuit 20 is limited and increase in the gate drive capability is inhibited. On the other hand, the gradual output of the constant output circuit 10 is combined, whereby a certain degree of gate drive capability is ensured. Therefore, in the gate driving device 100, change in the gate drive capability due to change in current in the main circuit is inhibited, and suppression of both switching loss and noise is achieved, so that robustness with respect to change in current in the main circuit is improved.

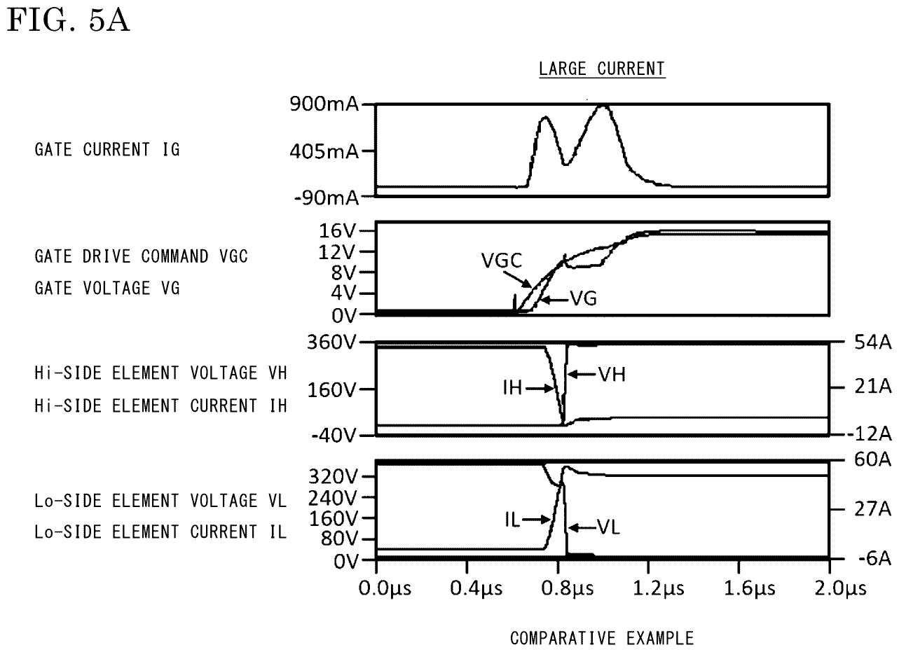

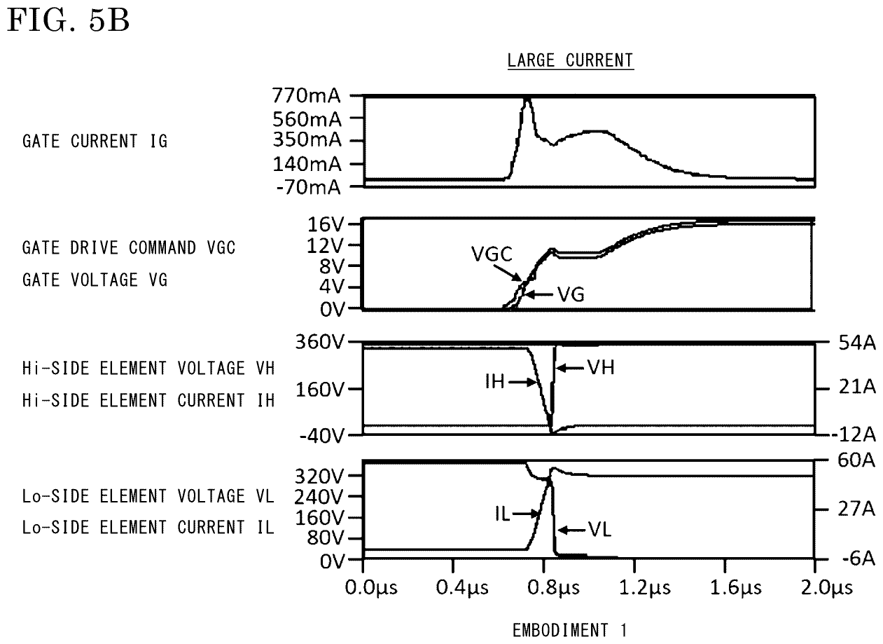

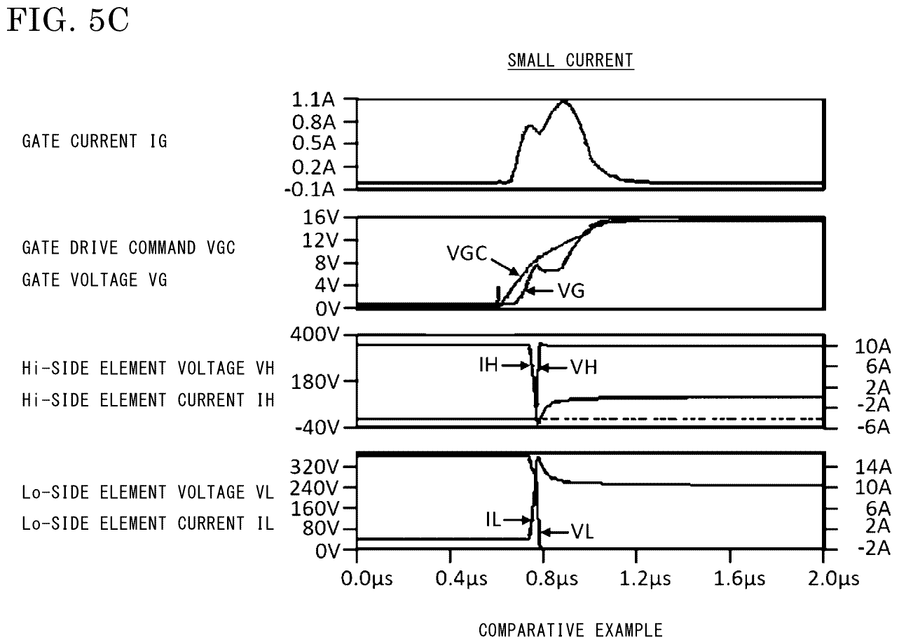

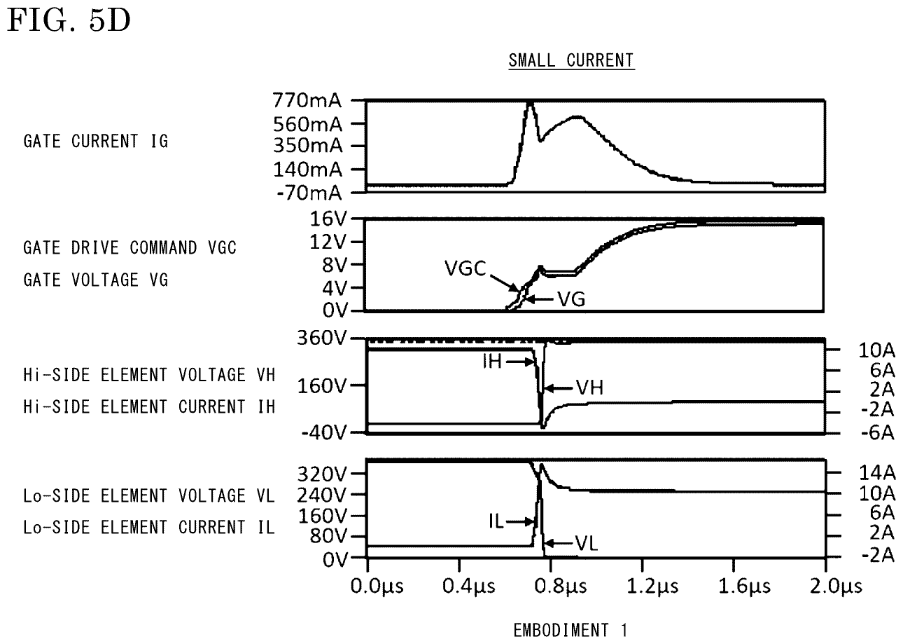

In order to describe the above-described improved robustness, a conventional gate driving device including the RC resonance circuit is used as a comparative example, and differences between the operation waveforms in the comparative example and the operation waveforms in embodiment 1 will be described. FIG. 5A shows operation waveforms according to the comparative example when a main circuit carries the large current, and FIG. 5B shows operation waveforms according to embodiment 1 when the main circuit carries the large current. In addition, FIG. 5C shows operation waveforms according to the comparative example when the main circuit carries the small current, and FIG. 5D shows operation waveforms according to embodiment 1 when the main circuit carries the small current. FIG. 5A to FIG. 5D each show an analysis result obtained by analyzing operation waveforms.

In each of FIG. 5A to FIG. 5D, operation waveforms when the lower-side semiconductor switching element 92B in FIG. 2A and FIG. 2B is turned on are shown, and “gate current IG” refers to a current flowing in the gate terminal of the lower-side semiconductor switching element 92B. “Gate drive command VGC” and “gate voltage VG” refer to the output of the gate driving device 100 and a gate voltage (voltage between the gate and the emitter) of the lower-side semiconductor switching element 92B, respectively, and the gate drive command VGC corresponds to the gate drive voltage Vgate. “Hi-side element voltage VH” and “Hi-side element current IH” refer to a voltage (voltage between the collector and the emitter) of the upper-side semiconductor switching element 92A, and a current (collector current) of the upper-side semiconductor switching element 92A, and correspond to VCE_H and IC_H in FIG. 3 to FIG. 4B, respectively. “Lo-side element voltage VL” and “Lo-side element current IL” refer to a voltage (voltage between the collector and the emitter) of the lower-side semiconductor switching element 92B and the current (collector current) of the lower-side semiconductor switching element 92B, and correspond to VCE_L and IC_L in FIG. 3 to FIG. 4B, respectively.

As a condition in the above-described analysis, both the circuit constant for the RC resonance circuit in the comparative example and the circuit constant for the RC resonance circuit of the command generation circuit 20 in embodiment 1 are set so as to correspond to the case where the main circuits carry the large current.

Looking at the waveforms in the comparative example in FIG. 5A and FIG. 5C, in the comparative example, it is found that an increase amount when the large current is carried and an increase amount when the small current is carried of the gate current IG are different from each other during the Miller period and the gate drive capability is increased when the small current is carried. Therefore, in the comparative example, change in recovery voltage with respect to time is increased and noise is increased as described above.

Meanwhile, as found through comparison of FIG. 5C and FIG. 5D, the gate current IG during the Miller period when the small current is carried can be further inhibited in embodiment 1 than in the comparative example, and change in recovery voltage with respect to time can also be inhibited. As described above, differences between the conventional gate driving device and that in the embodiment 1 can be confirmed also from the analysis result. Even if a plurality of targeted semiconductor switching elements are connected in parallel to each other, the gate driving device 100 may be structured so as to have the same circuit configuration as that shown in FIG. 1, with respect to the gate driving device for each switching element.

### EMBODIMENT 2

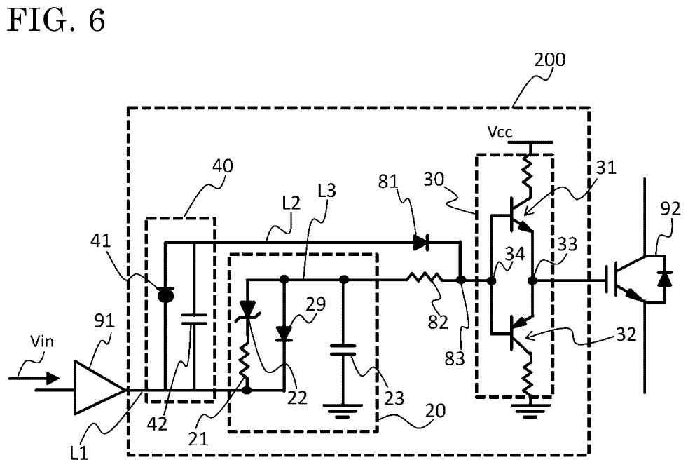

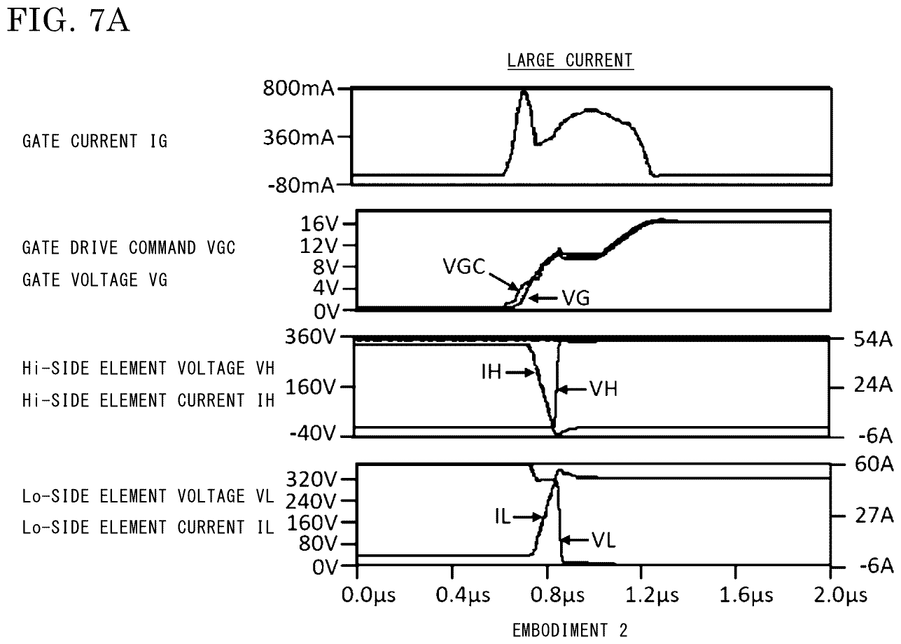

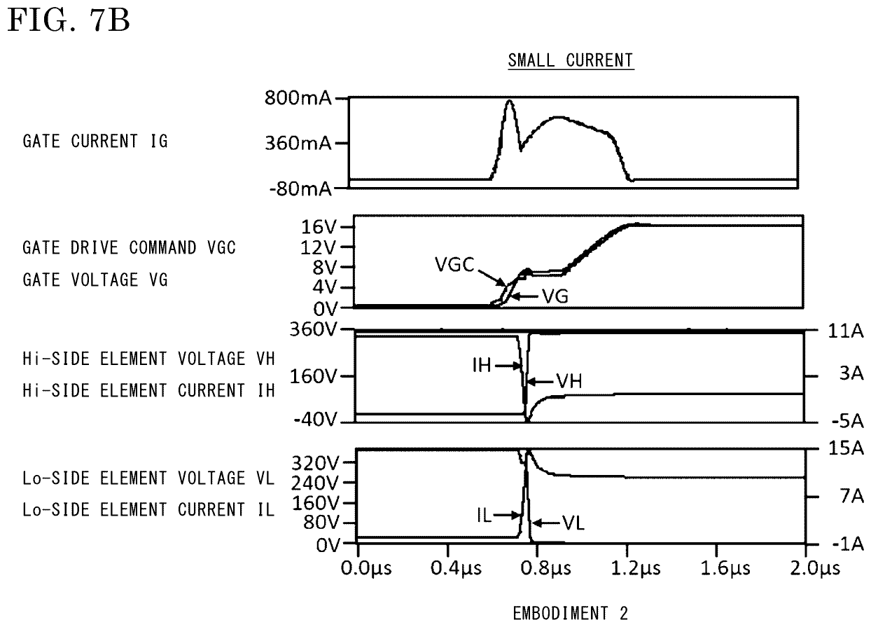

Next, embodiment 2 will be described with reference to FIG. 6 to FIG. 7B. FIG. 6 is a circuit diagram showing a gate driving device in embodiment 2. Parts that are the same as or correspond to those shown in FIG. 1 to FIG. 5D are denoted by the same reference characters, and the description thereof is omitted. A gate driving device 200 includes a constant output circuit 40 different from the constant output circuit 10 of the gate driving device 100. The constant output circuit 40 of the gate driving device 200 includes a constant current diode 41, that is, a constant current element, and a capacitor 42 connected in parallel to each other, and is a constant-current output circuit which outputs a constant current signal. One end of each of the constant current diode 41 and the capacitor 42 is connected to the electric path L1 on the ground side, and the other end thereof is connected to the electric path L2 on the high-potential side. Other configurations are the same as those of the gate driving device 100.

Next, operation of the gate driving device 200 of embodiment 2 will be described. FIG. 7A shows operation waveforms according to embodiment 2 when a main circuit carries the large current. In addition, FIG. 7B shows operation waveforms according to embodiment 2 when the main circuit carries the small current. Basic operations are the same as those in embodiment 1, and, after the gate drive is performed mainly using the command generation circuit 20, the gate drive is switched so as to be performed using the output of the constant output circuit 40. The constant output circuit 40 of embodiment 2 is a constant-current output circuit, and thus the gate current IG is constant even after the gate drive has been switched so as to be performed using the constant output circuit 40. Accordingly, the rate of increase in the gate voltage VG is also constant. Since the constant output circuit 10 of embodiment 1 is a constant voltage output circuit, the gate current IG changes without becoming constant particularly when small current is carried. For example, when FIG. 5D and FIG. 7B are compared with respect to the gate current IG during the period from 0.8 us to 1.2 μs, in embodiment 1 in FIG. 5D, the gate current IG exhibits swelling in the case of small current, but in embodiment 2 in FIG. 7B, the gate current IG remains almost the same. When the gate current IG is constant as in embodiment 2, the gate drive capability is more maintained and robustness with respect to change in the main circuit current is great. Thus, robustness with respect to the main circuit current can be further improved in embodiment 2.

In addition, the constant current diode has a characteristic of a small temperature dependence. This means that change in the gate drive capability due to temperature change can also be inhibited, so that robustness with respect to temperature change is also improved in embodiment 2.

### EMBODIMENT 3

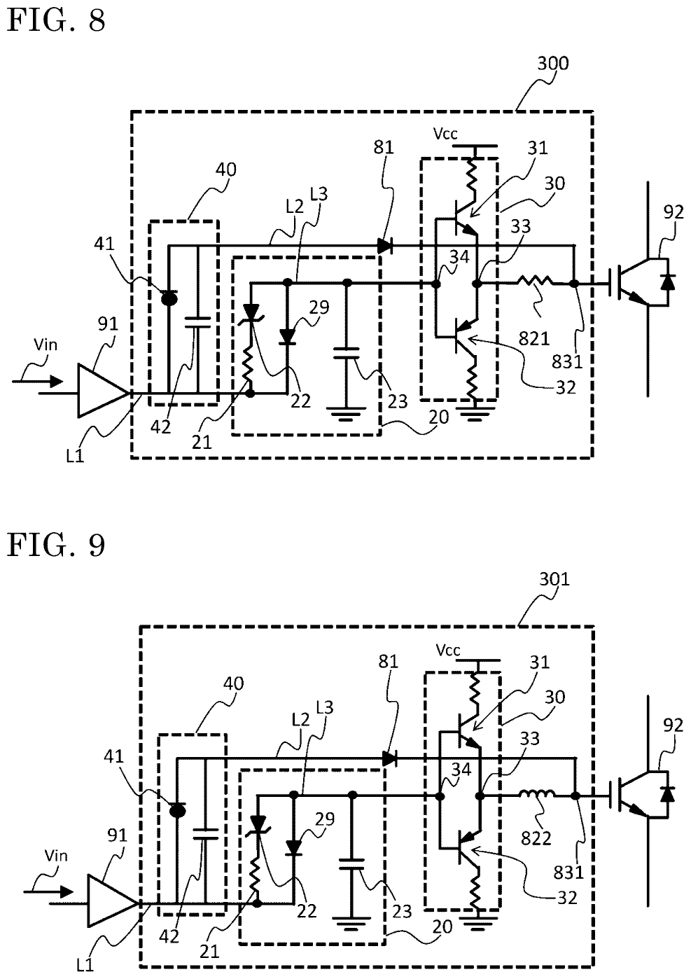

Next, embodiment 3 will be described with reference to FIG. 8. FIG. 8 is a circuit diagram showing a gate driving device in embodiment 3. Parts that are the same as or correspond to those shown in FIG. 1 to FIG. 7B are denoted by the same reference characters, and the description thereof is omitted. A gate driving device 300 is different from that in embodiment 2 in that an output terminal of the constant output circuit 40 is connected to the output side of the complementary emitter follower circuit 30. In the gate driving device 300, a current limitation element 821 and a connection point 831 are provided on the output side of the complementary emitter follower circuit 30, unlike the gate driving device 100 and the gate driving device 200 in which the current limitation element 82 and the connection point 83 are provided between the command generation circuit 20 and the complementary emitter follower circuit 30. The connection point 831 is provided between the current limitation element 821 and the gate terminal of the semiconductor switching element 92. At the connection point 831, the constant output circuit 40 is connected to the output side of the complementary emitter follower circuit 30. In embodiment 3, a resistor is used as the current limitation element 821. Other configurations are the same as those of the gate driving device 200. Between embodiments 1 and 2 and embodiment 3, there is a difference in whether the output of the constant output circuit 10 or the constant output circuit 40 and the output of the command generation circuit 20 are combined on the input side or the output side of the complementary emitter follower circuit 30, but the basic operations are similar to each other.

Since, in the gate driving device 300, the output terminal of the constant output circuit 40 is connected between the gate terminal of the semiconductor switching element 92, and the current limitation element 821 and the complementary emitter follower circuit 30, after the gate drive voltage Vgate has become greater than the Miller voltage Vmiller of the semiconductor switching element 92, the backflow of current is suppressed by the effect of the electromotive voltage of the current limitation element 821, and thus the complementary emitter follower circuit 30 can be suppressed from absorbing current. Thus, the constant output circuit 40 can maintain normal operation, and the effect as in embodiment 1 and embodiment 2 can be obtained.

In embodiment 3, the resistor is used as the current limitation element, but a reactor may be used as the current limitation element as in a modification of embodiment 3 shown in FIG. 9. In a gate driving device 301, the current limitation element 821 of the gate driving device 300 is replaced with a current limitation element 822 which is a reactor.

### EMBODIMENT 4

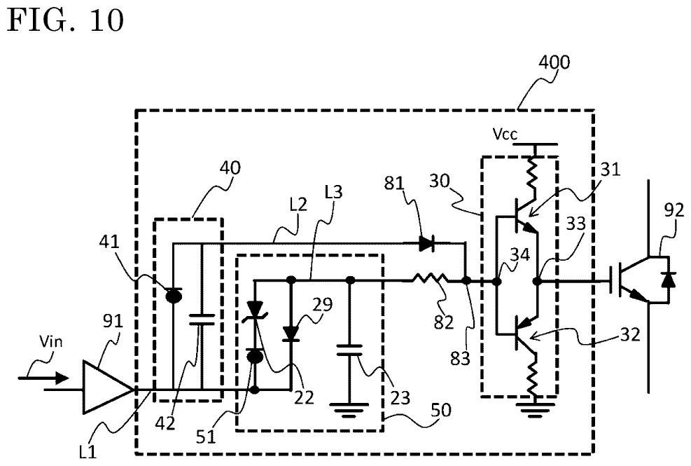

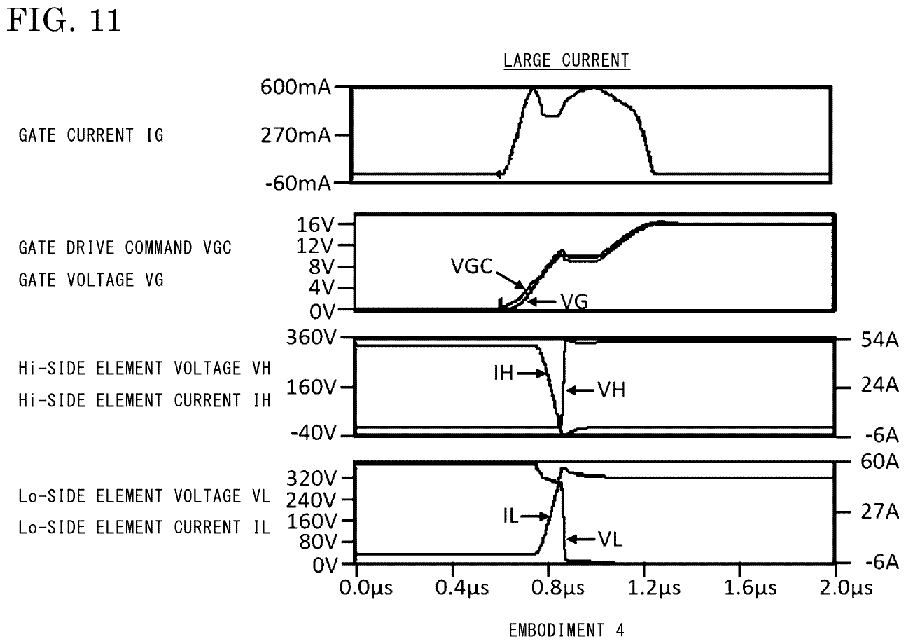

Next, embodiment 4 will be described with reference to FIG. 10 and FIG. 11. FIG. 10 is a circuit diagram showing a gate driving device in embodiment 4. Parts that are the same as or correspond to those shown in FIG. 1 to FIG. 9 are denoted by the same reference characters, and the description thereof is omitted. A gate driving device 400 includes a command generation circuit 50 different from the command generation circuit 20 of the gate driving device 200. That is, the command generation circuit 20 includes the RC resonance circuit composed of the resistor and the capacitor, but the command generation circuit 50 includes a constant-current output circuit composed of a constant current element and a capacitor. The command generation circuit 50 is composed of a series-connected assembly of the zener diode 22 and a constant current diode 51, the diode 29, and the capacitor 23 connected in parallel to each other. The constant current diode 51 is provided between the electric path L1 on the ground side and the electric path 13 on the high-potential side, and is connected to the cathode of the zener diode 22 on the high-potential side. The capacitor 23 and the diode 29 are the same as those in embodiment 2. The output of the command generation circuit 50 is inputted to the complementary emitter follower circuit 30 via the current limitation element 82 and the connection point 83 as in embodiment 2. Other configurations are the same as those of the gate driving device 200.

Next, operations of the gate driving device 400 of embodiment 4 will be described. FIG. 11 shows operation waveforms according to embodiment 4, when a main circuit carries the large current. Basic operations are the same as those in embodiment 2. However, when the gate drive command VGC and the gate voltage VG rise, the waveform in rising represents a parabola in embodiment 2 shown in FIG. 7A, but the gate drive command VGC and the gate voltage VG linearly rise in embodiment 4. In the case where the gate drive command VGC and the gate voltage VG linearly rise, even if the Miller voltage is changed due to change in the main circuit current, a certain gate drive capability is maintained. Thus, robustness with respect to change in the main circuit current in embodiment 4 is further improved than that in embodiment 2.

In addition, the constant current diode has a smaller temperature dependence than the resistor. Thus, robustness with respect to temperature change is also further improved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the technical scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

10, 40 constant output circuit
11, 21 resistor
20, 50 command generation circuit
22 zener diode
23, 42 capacitor
30 complementary emitter follower circuit
83, 831 connection point
41, 51 constant current diode
29, 81 diode
82, 821, 822 current limitation element
92 semiconductor switching element
92A upper-side semiconductor switching element
92B lower-side semiconductor switching element
100, 100A, 100B, 200, 300, 301, 400 gate driving device
Vin input signal

1-12. (canceled)

13. A gate driving device comprising:
a command generation circuit which generates and outputs a gate drive command on the basis of an input signal;
a constant output circuit which is connected in parallel to the command generation circuit and outputs a constant voltage signal or a constant current signal on the basis of the input signal;
an amplification circuit to which the constant voltage signal or the constant current signal is inputted and which amplifies the gate drive command; and
a current limitation element which is provided on an input side or an output side of the amplification circuit and which suppresses a backflow of current, wherein
the gate driving device applies a gate drive voltage obtained by combining the gate drive command and the constant voltage signal or the constant current signal, to a gate terminal of a semiconductor switching element.

14. The gate driving device according to claim 13, wherein
the command generation circuit includes a constant voltage element which is to clamp a voltage at a certain voltage lower than a power supply voltage of the amplification circuit so as to keep the gate drive command at the certain voltage.

15. The gate driving device according to claim 13, wherein
the command generation circuit includes an RC resonance circuit composed of a capacitor and a resistor connected in parallel to each other.

16. The gate driving device according to claim 13, wherein
when a gate voltage of the semiconductor switching element rises, the command generation circuit controls change of the gate voltage with respect to time to be constant.

17. The gate driving device according to claim 13, wherein
the command generation circuit includes a constant current element and a capacitor connected in parallel to each other.

18. The gate driving device according to claim 13, wherein
the current limitation element is provided between an output side of the command generation circuit and the input side of the amplification circuit, and
a connection point to which an output end of the constant output circuit is connected is provided between the current limitation element and the input side of the amplification circuit.

19. The gate driving device according to claim 13, wherein
the current limitation element includes at least one of a resistor or a reactor.

20. The gate driving device according to claim 14, wherein
in a case where an output current of the constant output circuit is represented by Iconst, an output current of the command generation circuit is represented by Iact, the gate drive voltage is represented by Vgate, and the certain voltage is represented by Vz, inequality (1) is satisfied.
$$[ Math . 1 ]$$
$$\{ \begin{matrix}{I}_{act} > {I}_{const} ( {V}_{z} \geq {V}_{gate} ) \\ {I}_{const} \geq {I}_{act} ( {V}_{gate} > {V}_{z} )\end{matrix} . \qquad ( 1 )$$

21. The gate driving device according to claim 14, wherein
the constant voltage element is a zener diode whose breakdown voltage is the certain voltage.

22. The gate driving device according to claim 14, wherein
the certain voltage is equal to a Miller voltage of the semiconductor switching element.

23. The gate driving device according to claim 13, wherein
the amplification circuit is a complementary emitter follower circuit or a complementary source follower circuit.

24. A gate driving device comprising:
a command generation circuit which generates and outputs a gate drive command on the basis of an input signal;
a constant output circuit which is connected in parallel to the command generation circuit and outputs a constant voltage signal or a constant current signal on the basis of the input signal;
an amplification circuit which amplifies the gate drive command; and
a current limitation element which is provided on an input side or an output side of the amplification circuit and which suppresses a backflow of current, wherein
the gate driving device applies a gate drive voltage obtained by combining the gate drive command and the constant voltage signal or the constant current signal, to a gate terminal of a semiconductor switching element, and
the command generation circuit includes a constant voltage element which is to clamp a voltage at a certain voltage lower than a power supply voltage of the amplification circuit so as to keep the gate drive command at the certain voltage.

25. The gate driving device according to claim 24, wherein
the current limitation element is provided between the output side of the amplification circuit and the gate terminal, and
a connection point to which an output end of the constant output circuit is connected is provided between the current limitation element and the gate terminal.

26. A gate driving device comprising:
a command generation circuit which generates and outputs a gate drive command on the basis of an input signal;
a constant output circuit which is connected in parallel to the command generation circuit and outputs a constant voltage signal or a constant current signal on the basis of the input signal;
an amplification circuit which amplifies the gate drive command; and
a current limitation element which is provided on an input side or an output side of the amplification circuit and which suppresses a backflow of current, wherein
the gate driving device applies a gate drive voltage obtained by combining the gate drive command and the constant voltage signal or the constant current signal, to a gate terminal of a semiconductor switching element, and
the command generation circuit includes a constant current element and a capacitor connected in parallel to each other.

27. The gate driving device according to claim 26, wherein
the current limitation element is provided between the output side of the amplification circuit and the gate terminal, and
a connection point to which an output end of the constant output circuit is connected is provided between the current limitation element and the gate terminal.
